(19) United States
(12) Patent Application Publication
(10) Pub. No.: US 2007/0169928 A1
(43) Pub. Date: Jul. 26, 2007

(54) Heat sink for controlling dissipation of a thermal load

(76) Inventors: Richard A. Dayan, Wake Forest, NC (US); Dean F. Herring, Youngsville, NC (US)

Correspondence Address: IBM (RPS-BLF);c/o BIGGERS & OHANIAN, LLP, P.O. BOX 1469, AUSTIN, TX, 78767-1469, US

(21) Appl. No.: 11/340,050

(22) Filed: Jan. 26, 2006

(51) Int. Cl. H05K 7/20

(52) U.S. Cl. 165/287; 165/80.3; 361/704

(57) ABSTRACT

A heat sink for controlling dissipation of a thermal load is disclosed that includes a heat sink base receiving the thermal load, an actuator connected to the heat sink base, the actuator having a temperature dependent upon the thermal load, the actuator configured in dependence upon the temperature of the actuator, and an adaptable fin connected to the actuator and shaped according to the configuration of the actuator so as to control dissipation of the thermal load.

### BACKGROUND OF THE INVENTION

1. Field of the Invention

The field of the invention is heat sinks for controlling dissipation of a thermal load.

2. Description Of Related Art

The development of the EDVAC computer system of 1948 is often cited as the beginning of the computer era. Since that time, users have relied on computer systems to simplify the process of information management. Today's computer systems are much more sophisticated than early systems such as the EDVAC. Such modern computer systems deliver powerful computing resources to provide a wide range of information management capabilities through the use of computer software such as database management systems, word processors, spreadsheets, client/server applications, web services, and so on.

In order to deliver these powerful computing resources, computer architects must design powerful computer processors. Current computer processors, for example, are capable of executing billions of computer program instructions per second. Computer architects design these computer processors to operate under a specific set of operating environment conditions to prevent damage to the computer processor. Such operating environment conditions include operating temperature ranges, voltage ranges, current ranges, power ranges, electromagnetic field tolerances, and so on.

To maintain the operating temperature of a computer processor within an operating temperature range, computer architects often utilize heat sinks. Current heat sinks provide one or two cooling surfaces with attached fins for dissipating the heat absorbed by the heat sinks. Such heat sinks are often effective at maintaining the operating temperature of the computer processor below the upper boundary of the operating temperature range. Current heat sinks, however, do not provide an effective solution for maintaining the operating temperature of the computer processor both below the upper boundary and above the lower boundary of the operating temperature range.

### SUMMARY OF THE INVENTION

A heat sink for controlling dissipation of a thermal load is disclosed that includes a heat sink base receiving the thermal load, an actuator connected to the heat sink base, the actuator having a temperature dependent upon the thermal load, the actuator configured in dependence upon the temperature of the actuator, and an adaptable fin connected to the actuator and shaped according to the configuration of the actuator so as to control dissipation of the thermal load.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a perspective view of an exemplary heat sink for controlling dissipation of a thermal load according to embodiments of the present invention.

FIG. 2 sets forth a perspective view of a further exemplary heat sink for controlling dissipation of a thermal load according to embodiments of the present invention.

FIG. 3 sets forth a perspective view of a further exemplary heat sink for controlling dissipation of a thermal load according to embodiments of the present invention.

FIG. 4 sets forth a top plan view of a further exemplary heat sink for controlling dissipation of a thermal load according to embodiments of the present invention.

### DETAILED DESCRIPTION OF EXEMPLARY EMBODIMENTS

### Detailed Description

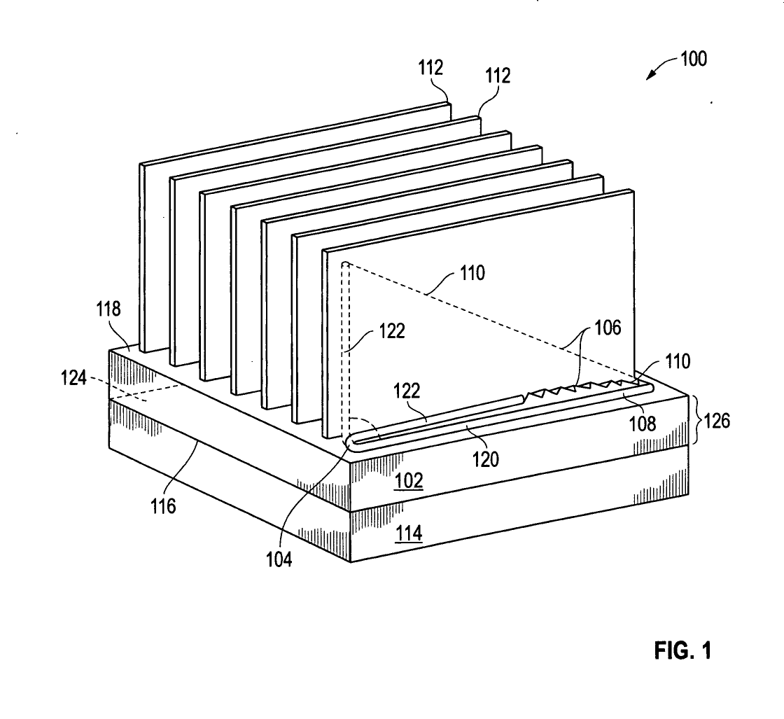

Exemplary heat sinks for controlling dissipation of a thermal load according to embodiments of the present invention are described with reference to the accompanying drawings, beginning with FIG. 1. FIG. 1 sets forth a perspective view of an exemplary heat sink (100) for controlling dissipation of a thermal load according to embodiments of the present invention. The thermal load is the rate of thermal energy produced with respect to time from the operation of an integrated circuit package (114) such as, for example, a computer processor or memory chip. A measure of thermal load is typically expressed in units of Watts.

In the example of FIG. 1, the heat sink (100) is a thermal conductor configured to absorb and dissipate the thermal load from the integrated circuit package (114) thermally connected with the heat sink (100). Thermal conductors used in designing the heat sink (100) may include, for example, aluminum, copper, silver, aluminum silicon carbide, or carbon-based composites. Heat sink (100) absorbs the thermal load from the integrated circuit package through thermal conduction. When thermally connecting the heat sink (100) to the integrated circuit package (114), the heat sink provides additional thermal mass, cooler than the integrated circuit package (114), into which the thermal load may flow. After absorbing the thermal load, the heat sink (100) dissipates the thermal load through thermal convection and thermal radiation into the environment surrounding the heat sink (100). Though the heat sink (100) dissipates the thermal load through both thermal convection and thermal radiation, dissipation of the thermal load is primarily affected through thermal convection at the surfaces of the heat sink (100). Increasing the surface area of the heat sink (100) typically increases the rate of dissipating the thermal load. The surface area of the heat sink (100) may be increased by enlarging a base of the heat sink or increasing the number of heat-dissipating fins.

The example heat sink (100) of FIG. 1 includes a heat sink base (102) receiving the thermal load. The heat sink base (102) is a plate generally shaped as a rectangular box. The dimensions of the bottom surface of the heat sink base (102) conform to the dimensions of the top surface of the integrated circuit package (114). The heat sink base (102) in the example of FIG. 1 connects to the integrated circuit package (114) by a thermal interface (116). The thermal interface (116) is a thermally conductive material that reduces the thermal resistance associated with transferring the thermal load from the integrated circuit package (114) to the heat sink (100). The thermal interface (116) between the integrated circuit package (114) and the heat sink base (102) has less thermal resistance than could typically be produced by connecting the integrated circuit package (114) directly to the heat sink base (102). Decreasing the thermal resistance between the integrated circuit package (114) and the heat sink base (102) increases the efficiency of transferring the thermal load from the integrated circuit package (114) to the heat sink base (102). The thermal interface (116) in the example of FIG. 1 may include non-adhesive materials such as, for example, thermal greases, phase change materials, and gap-filling pads. The thermal interface (116) may also include adhesive materials such as, for example, thermosetting liquids, pressure-sensitive adhesive (‘PSA’) tapes, and thermoplastic or thermosetting bonding films.

The heat sink (100) in the example of FIG. 1 also includes rigid heat-dissipating fins (112). The rigid heat-dissipating fins (112) are thermal conductors that provide additional surface area to heat sink (100) for dissipating the thermal load. The rigid heat-dissipating fins (112) dissipate the thermal load into the environment adjacent the surfaces of the rigid heat-dissipating fins (112). The rigid heat-dissipating fins (112) extend spaced apart in parallel from the top surface (118) of the heat sink base (102) to a height that is limited by the physical restrictions of the environment surrounding the heat sink such as, for example, the shape of an enclosure that contains the integrated circuit (114) and heat sink (100) or the placement of other components inside the enclosure. The rigid heat-dissipating fins (112) connect to the heat sink base (102) by extrusion. The extruded rigid heat-dissipating fins (112) in the example of FIG. 1 are for explanation only, and not for limitation. The rigid heat-dissipating fins (112) may also connect to each heat sink base (102) by bonding the rigid heat-dissipating fins (112) to each heat sink base (102) through the use of epoxy, press-fit, brazing, welding, or other connections as may occur to those of skill in the art.

In the example heat sink (100) of FIG. 1, manufacturing capabilities may restrict the thickness of the rigid heat-dissipating fins (112) and number of rigid heat-dissipating fins (112) connected to the heat sink base (102). While thinner fins and smaller gaps between fins may allow a heat sink designer to place more fins on a particular heat sink base (102), thinner fins and smaller gaps between fins may also limit the height of the fins. Extruded rigid heat-dissipating fins (112) in the example heat sink (100) depicted in FIG. 1 typically have fin height-to-gap aspect ratios of up to 6 and a minimum fin thickness of 1.3 millimeters. Special die design features may, however, increase the height-to-gap aspect ratio to 10 and decrease the minimum fin thickness to 0.8 millimeters. For example, given a maximum rigid heat-dissipating fin (112) height of 30 millimeters and a fin height-to-gap aspect ratio of 6, the minimum gap between rigid heat-dissipating fins (112) is calculated as follows:
G=H÷R=30÷6=5 millimeters
where G is the gap between the heat-dissipating fins, H is the height of the heat-dissipating fins, and R is the fin height-to-gap aspect ratio.

After obtaining the minimum gap between rigid heat-dissipating fins (112), the number of rigid heat-dissipating fins (112) is calculated as the quantity of the width of the plate plus the gap between fins divided by the quantity of the fin thickness plus the gap. Continuing with the previous example, given a heat sink base (102) width of 60 millimeters and a fin thickness of 1.3 millimeters, the maximum number of rigid heat-dissipating fins (112) connected the heat sink base (102) is calculated as follows:
N=(W+G)÷(F+G)=(60+5)÷(1.3+5)=10.3 fins
where N is the number of heat-dissipating fins that a plate may accommodate, W is the width of the plate, G is the gap between the heat-dissipating fins, and F is the thickness of the rigid heat-dissipating fins. This calculation for the maximum number of fins yields 10.3 fins, meaning that in this example, the plate may accommodate 10 fins.

The example heat sink (100) of FIG. 1 also includes an actuator (104) connected to the heat sink base (102). The actuator (104) is a thermomorphic component used for expanding and retracting an adaptable fin (106) that includes a lower region (120) and an upper region (122). The lower region (120) of the actuator (104) connects to the heat sink base (102) along the top surface (118) of the heat sink base (102) by an adhesive thermal interface. The lower region (120) of the actuator (104) is oriented in parallel to the rigid heat-dissipating fins (112). Because the lower region (120) is in a fixed position relative to the heat sink base (104), the thermomorphic nature of the actuator (104) causes the upper region (122) of the actuator (104) to change position relative to the heat sink base (102) in dependence upon the temperature of the actuator (104). As the temperature of the actuator (104) changes, the geometric relationship between the upper region (122) of the actuator (104) and the lower region (120) of the actuator (104) changes between substantially parallel and substantially perpendicular.

In the example of FIG. 1, the actuator (104) has a temperature dependent upon the thermal load. The temperature of the actuator (104) results from heat flow from the integrated circuit package (114) to the actuator (104) through the heat sink base (102). The temperature of the actuator (104) may be calculated as the temperature at the top surface (118) of the heat sink base (102) minus the quantity of the thermal load times the proportion of the thermal load flowing through the actuator (104) times the thermal resistance between the heat sink base (102) and the actuator (104). Because the temperature of the actuator (104) depends on temperature of at the top surface (118) of the heat sink base (102), the temperature at the top surface (118) of the heat sink base (102) must also be calculated. The temperature at the top surface (118) of the heat sink base (102) may be calculated as the temperature of the bottom surface (124) of the heat sink base (102) minus the quantity of the thermal load times the thickness (126) of the heat sink base (102) divided by the thermal conductivity of the base plate (102) divided by the area of the top surface (118) of the heat sink base (102). Because the temperature at the top surface (118) of the heat sink base (102) depends on the temperature of the bottom surface (124) of the heat sink base (102), the temperature of the bottom surface (124) of the heat sink base (102) must be calculated as well. The temperature of the bottom surface (124) of the heat sink base (102) may be calculated as the temperature of the integrated circuit package (114) minus the quantity of the thermal load times the thermal resistance between the integrated circuit package (114) and the heat sink base (102).

For an example of calculating the temperature of the actuator (104) dependent upon the thermal load, consider a heat sink for controlling the dissipation of a thermal load where the temperature of the integrated circuit package (114) is 70 degrees Celsius, the thermal load is 100 Watts, the thermal resistance between the integrated circuit package (114) and the heat sink base (102) is 0.1 degrees Celsius per Watt, the thermal resistance between the heat sink base (102) and the actuator (104) is 0.1 degrees Celsius per Watt, the thermal conductivity of the base plate (102) is 240 Watts per meter per Kelvin, the thickness (126) of the heat sink base (102) is 0.01 meters, the area of the top surface (118) of the heat sink base (102) is 0.0036 square meters, and the proportion of the thermal load flowing through the actuator (104) is 10 percent. As mentioned above, to calculate the temperature of the actuator (104), the temperature of the top surface (118) of the heat sink base (102) and the temperature of the bottom surface (124) of the heat sink base (102) must first be calculated. The temperature of the bottom surface (124) of the heat sink base (102) may be calculated as follows:
T_{BS}=T_{IC}−(P*R_{IC-HSB})=70−(100*0.1)=60 degrees Celsius
where T_{BS} is the temperature of the bottom surface (124) of the heat sink base (102), T_{IC} is the temperature of the integrated circuit package (114), P is the thermal load, and R_{IC-HSB} is the thermal resistance between the integrated circuit package (114) and the heat sink base (102). After calculating the temperature of the bottom surface (124), the temperature of the top surface (118) of the heat sink base (102) may be calculated as follows:
T_{TS}=T_{BS}−(P*D÷K÷A)−273.15=60−(100*0.01÷240÷0.0036)=58.8 degrees Celsius
where T_{TS} is the temperature of the top surface (118) of the heat sink base (102), T_{BS} is the temperature of the bottom surface (124) of the heat sink base (102), P is the thermal load, D is the thickness (126) of the heat sink base (102), K is the thermal conductivity of the base plate (102), and A is the area of the top surface (118) of the heat sink base (102). After calculating the temperature of the bottom surface (124), the temperature of the actuator (104) may be calculated as follows:
T_{ACT}=T_{TS}−(P*L*R_{HSB-ACT})=58.8−(100*0.1*0.1)=57.8 degrees Celsius
where T_{ACT} is the temperature of the actuator (104), T_{TS} the temperature at the top surface (118) of the heat sink base (102), P is the thermal load, L is the proportion of the thermal load flowing through the actuator (104), and R_{HSB-ACT} is the thermal resistance between the heat sink base (102) and the actuator (104).

As mentioned above, the actuator (104) is a thermomorphic component. In the example of FIG. 1, therefore, the actuator (104) is configured in dependence upon the temperature of the actuator (104). That is, the geometry of the actuator (104) changes in dependence upon the temperature of the actuator. The actuator (104) in the example heat sink (100) of FIG. 1 is implemented as a wire (108) of a shape memory alloy. The term shape memory alloy is applied to the group of metallic materials that demonstrate the ability to return to some previously defined shape or size when subjected to the appropriate thermal stimulus. Shape memory alloys can be configured in a first geometry while at a low temperature and configured in a second geometry while at a relatively higher temperature with respect to the low temperature. Upon exposure to the low temperature, shape memory alloys will return to the configuration of the first geometry. Upon exposure to the relatively higher temperature, shape memory alloys will return to the configuration of the second geometry. The ability of a shape memory alloy to return to a previously defined configuration is due to a temperature-dependent phase transformation from a low-symmetry crystallographic structure to a high-symmetry crystallographic structure. The low-symmetry crystallographic structure is known as martensite. The high-symmetry crystallographic structure is known as austenite. The transition temperatures at which shape memory alloys change their crystallographic structures from martensite to austenite and from austenite to martensite are characteristics of each alloy. These transition temperatures can be tuned by varying the elemental ratios of each element included in the shape memory alloy.

In the example of FIG. 1, the shape memory alloy is nitinol. Nitinol is the generic trade name for alloys that include Nickel and Titanium. Scientists discovered these alloys in the early 1960s at the Naval Ordinance Laboratory. The term “nitinol” is derived from the concatenation of the abbreviations of Nickel (“Ni”), Titanium (“Ti”), and the Naval Ordinance Laboratory (“NOL”). Although the shape memory alloy in the example heat sink (100) of FIG. 1 is nitinol, other shape memory alloys may also be used in a heat sink for controlling dissipation of a thermal load according to embodiments of the present invention. Other shape memory alloys useful in a heat sink for controlling dissipation of a thermal load may include, for example, alloys made of Copper (“Cu”), Zinc (“Zn”), and Aluminium (“Al”) and alloys made of Copper (“Cu”), Aluminium (“Al”), and Nickel (“Ni”).

The heat sink (100) in the example of FIG. 1 also includes an adaptable fin (106) connected to the actuator (104). The adaptable fin (106) is a sheet of pliable material capable of being collapsed or expanded by the actuator (104). In the example of FIG. 1, the adaptable fin (106) is generally triangular in shape when expanded. The bottom edge of the adaptable fin (106) connects to the actuator (104) along the lower region (120) of the actuator (104) and the left edge of the adaptable fin (106) connects to the upper region (122) of the actuator (104). The adaptable fin (106) connects to the actuator (104) by bonding the adaptable fin (106) to the actuator (104) through the use of an adhesive thermal interface, epoxy, brazing, welding, or other connections as may occur to those of skill in the art.

In the example heat sink (100) of FIG. 1, the adaptable fin (106) is implemented as an adaptable heat-dissipating fin (110). The adaptable heat-dissipating fin (110) is a thermal conductor that provides additional surface area to heat sink (100) for dissipating the thermal load. The adaptable heat-dissipating fin (110) dissipates the thermal load into the environment adjacent the surfaces of the adaptable heat-dissipating fin (110). In the example heat sink (100) of FIG. 1, the adaptable heat-dissipating fin (110) is copper foil. Copper foil useful in a heat sink for controlling dissipation of a thermal load according to embodiments of the present invention includes, for example, conventional foils from Gould Electronics such as JTC™, JTCS™, RTC™, and RTCS™. In addition to copper foil, the adaptable heat-dissipating fin (110) may also be formed from other thermal conductors such as, for example, carbon nanotubes, silver, gold, thermally conductive fabrics, or any other thermal conductors as will occur to those of skill in the art.

In the example heat sink (100) of FIG. 1, the adaptable fin (106) is shaped according to the configuration of the actuator so as to control dissipation of the thermal load. That is, the geometry of the adaptable fin (106) changes as the position of the actuator (104) changes. Changes in the shape of the actuator (104) control the amount of surface area of the adaptable fin (106) exposed to the surrounding environment for dissipating the thermal load. When the actuator (104) collapses the adaptable fin (106), the amount of surface area of the adaptable fin (106) exposed to the surrounding environment is reduced. When the actuator (104) expands the adaptable fin (106), the amount of surface area of the adaptable fin (106) exposed to the surrounding environment is increased. As mentioned above, dissipation of the thermal load in the heat sink (100) occurs primarily through thermal convection through the surface of the heat sink (100) to the surrounding environment. Increasing the surface area of the adaptable fin (106) exposed to the surrounding environment therefore increases the rate of dissipation of the thermal load. Similarly, decreasing the surface area of the adaptable fin (106) exposed to the surrounding environment decreases the rate of dissipation of the thermal load. Therefore, as the actuators (104) expand and collapse the adaptable fins (106), the heat sink (100) controls the dissipation of the thermal load.

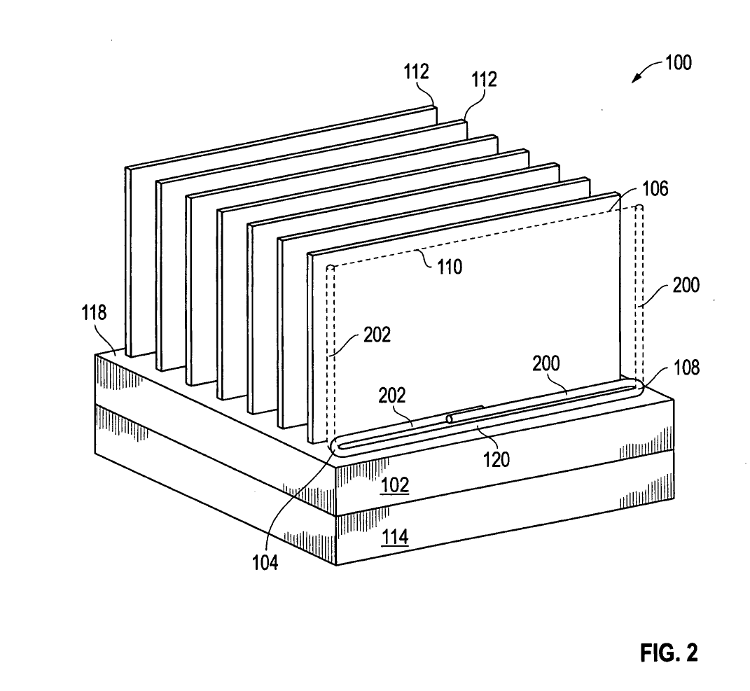

For further explanation, FIG. 2 sets forth a perspective view of a further exemplary heat sink for controlling dissipation of a thermal load according to embodiments of the present invention. The example heat sink (100) of FIG. 2 is similar in structure to the example heat sink of FIG. 1. That is, similar to the example heat sink of FIG. 1 in that: The example heat sink (100) of FIG. 2 includes a heat sink base (102) receiving the thermal load. The heat sink base (102) receives the thermal load from an integrated circuit package (114). The example heat sink (100) of FIG. 2 includes rigid heat-dissipating fins (112). The example heat sink (100) of FIG. 2 includes an actuator (104) connected to the heat sink base (102). The actuator (104) has a temperature dependent upon the thermal load. The actuator (104) is configured in dependence upon the temperature of the actuator (104). The example heat sink (100) of FIG. 2 also includes an adaptable fin (106) connected to the actuator (104). The adaptable fin (106) is shaped according to the configuration of the actuator so as to control dissipation of the thermal load.

In the example heat sink (100) of FIG. 2, the actuator (104) is implemented as a wire (108) of a shape memory alloy. In the example of FIG. 2, the shape memory alloy is nitinol. The actuator (104) includes a lower region (120), a right upper region (200), and a left upper region (202). The lower region (120) of the actuator (104) connects to the heat sink base (102) along the top surface (118) of the heat sink base (102) by an adhesive thermal interface. The lower region (120) of the actuator (104) is oriented in parallel to the rigid heat-dissipating fins (112). Because the lower region (120) is in a fixed position relative to the heat sink base (104), the thermomorphic nature of the actuator (104) causes the right upper region (200) of the actuator (104) and the left upper region (202) of the actuator (104) to change position relative to the heat sink base (102) in dependence upon the temperature of the actuator (104). As the temperature of the actuator (104) changes, the geometric relationship between the right upper region (200) of the actuator (104) and the lower region (120) of the actuator (104) therefore changes between substantially parallel and substantially perpendicular. Similarly, as the temperature of the actuator (104) changes, the geometric relationship between the left upper region (202) of the actuator (104) and the lower region (120) of the actuator (104) also changes between substantially parallel and substantially perpendicular.

In the example heat sink (100) of FIG. 2, the adaptable fin (106) is generally rectangular in shape. The bottom edge of the adaptable fin (106) connects to the actuator (104) along the lower region (120) of the actuator (104). The right edge of the adaptable fin (106) connects to the right upper region (200) of the actuator (104). The left edge of the adaptable fin (106) connects to the left upper region (202) of the actuator (104). The adaptable fin (106) connects to the actuator (104) by bonding the adaptable fin (106) to the actuator (104) through the use of an adhesive thermal interface, epoxy, brazing, welding, or other connections as may occur to those of skill in the art.

In the example heat sink (100) of FIG. 2, the adaptable fin (106) is implemented as an adaptable heat-dissipating fin (110). The adaptable heat-dissipating fin (110) is a thermal conductor that provides additional surface area to heat sink (100) for dissipating the thermal load. The adaptable heat-dissipating fin (110) dissipates the thermal load into the environment adjacent the surfaces of the adaptable heat-dissipating fin (110). In the example heat sink (100) of FIG. 1, the adaptable heat-dissipating fin (110) is a thermally conductive fabric. Thermally conductive fabrics useful in a heat sink for controlling dissipation of a thermal load according to embodiments of the present invention include, for example, the ThermaCool™ family of thermally conductive coated fabrics by Saint-Gobain Performance Plastics. In addition to thermally conductive fabrics, the adaptable heat-dissipating fin (110) may also be formed from other thermal conductors such as, for example, carbon nanotubes, silver, gold, copper, or any other thermal conductors as will occur to those of skill in the art.

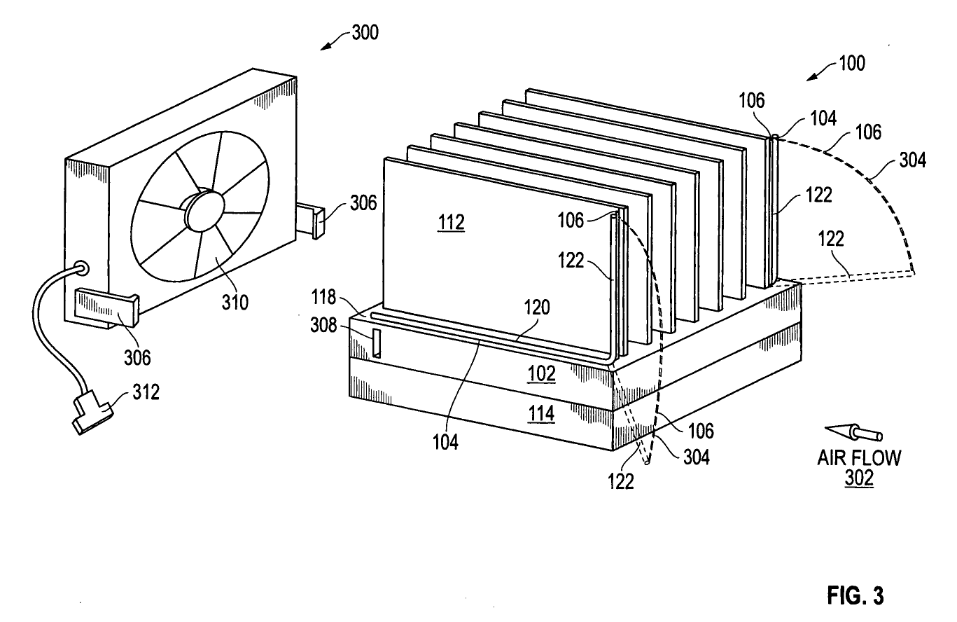

In the example heat sinks of FIGS. 1 and 2, readers will notice that the adaptable fins are shaped according to the configuration of the actuator so as to control dissipation of the thermal load by increasing and decreasing the thermally conductive surface area of heat sink as the actuator expands and retracts the adaptable fins. The adaptable fins, however, may also be shaped according to the configuration of the actuator so as to control dissipation of the thermal load by increasing and decreasing the air flow across the rigid heat-dissipating fins of the heat sink as the actuator expands and retracts the adaptable fins. For further explanation of an adaptable fin implemented as a baffle fin for increasing and decreasing the air flow across the rigid heat-dissipating fins, FIG. 3 sets forth a perspective view of a further exemplary heat sink (100) for controlling dissipation of a thermal load according to embodiments of the present invention. The example heat sink (100) of FIG. 3 is similar to the example heat sink of FIG. 1. That is, similar to the example heat sink of FIG. 1 in that: The example heat sink (100) of FIG. 3 includes a heat sink base (102) receiving the thermal load. The heat sink base (102) receives the thermal load from an integrated circuit package (114). The example heat sink (100) of FIG. 3 includes rigid heat dissipating fins (112) connected to the heat sink base (102).

The example heat sink (100) of FIG. 3 also includes a fan (300) oriented with respect to the rigid heat-dissipating fins (112) so as to induce air flow (302) across the rigid heat-dissipating fins (112). The air flow (302) is the rate at which a quantity of air flows across the rigid heat-dissipating fins (112) with respect to time. A measure of airflow is typically expressed in units of cubic meters per second. In the example of FIG. 3, the fan (300) connects to the heat sink base (102) by clips (306) mounted on the sides of fan (300). The clips (306) engage grooves (308) in the outer surface of the heat sink base (102). The depiction of the fan (300) connected to the heat sink base (102) by clips (306) and grooves (308) in the example of FIG. 3 is for explanation and not for limitation. In fact, the fan (300) need not connect to the heat sink base (102) at all. The fan (300) may mount to a circuit board adjacent to the heat sink base (102) such that the fan (300) is oriented with respect to the rigid heat-dissipating fins (112) so as to induce air flow (302) across the rigid heat-dissipating fins (112).

The fan (300) in the example of FIG. 3 induces air flow (302) across the heat-dissipating fins (112) by rotating fan blades (310). The fan blades (310) rotate under the power of a fan motor (not shown) that converts electrical energy to mechanical energy. The fan motor receives electrical energy from a power supply through electrical plug (312). The fan motor transmits power to the fan blades (310) through a shaft (not shown) connected with the fan blades (310) and the fan motor.

The example heat sink (100) of FIG. 3 also includes two actuators (104) connected to the heat sink base (102). Each actuator (104) is implemented as a wire of a shape memory alloy. In the example of FIG. 3, each actuator (104) has a temperature dependent upon the thermal load. Each actuator (104) is configured in dependence upon the temperature of the actuator (104). Each actuator (104) includes a lower region (120) and an upper region (122). The lower region (120) of each actuator (104) connects to the heat sink base (102) along the top surface (118) of the heat sink base (102) by an adhesive thermal interface. The lower region (120) of each actuator (104) is oriented in parallel to the rigid heat-dissipating fins (112) and connects to the heat sink base (102) adjacent to the outermost rigid heat-dissipating fin (112). Because the lower region (120) of each actuator (104) is in a fixed position relative to the heat sink base (102), the thermomorphic nature of each actuator (104) causes the upper region (122) of each actuator (104) to change position relative to the heat sink base (102) in dependence upon the temperature of each actuator (104). As the temperature of each actuator (104) changes, the geometric relationship between the upper region (122) of each actuator (104) and top surface (118) of the heat sink base (102) therefore changes between substantially parallel and substantially perpendicular.

The example heat sink (100) of FIG. 3 also includes two adaptable fins (106), each adaptable fin (106) connected to one of the actuators (104). As mentioned above, each adaptable fin (106) is a sheet of pliable material capable of being collapsed or expanded by the actuators (104). In the example of FIG. 3, each adaptable fin (106) is shaped generally as a sector of a circle when expanded. One radial edge of each adaptable fin (106) connects to one of the actuators (104) along the upper region (122) of the actuator (104). The other radial edge of each adaptable fin (106) connects to the rigid heat-dissipating fin (112) adjacent to the actuator (104) connected to the adaptable fin (106). The adaptable fins (106) connects to the actuators (104) and rigid heat-dissipating fins (112) by bonding the adaptable fins (106) to the actuators (104) and rigid heat-dissipating fins (112) through the use of an adhesive thermal interface, epoxy, brazing, welding, or other connections as may occur to those of skill in the art.

In the example of FIG. 3, the adaptable fin (106) is shaped according to the configuration of the actuator (104) so as to control dissipation of the thermal load. That is, the geometry of the adaptable fin (106) changes as the position of the actuator (104) changes. To control dissipation of the thermal load, each adaptable fin (106) in the example of FIG. 3 is implemented as a baffle fin (304) configured so as to control the air flow (302) across the rigid heat-dissipating fins (112). In the example heat sink (100) of FIG. 3, the baffle fin (304) is plastic. In addition to plastic, the baffle fin (304) may also be formed from other materials such as thermal conductors. Such thermal conductors may include, for example, carbon nanotubes, silver, gold, copper, thermally conductive fabrics, or any other thermal conductors as will occur to those of skill in the art.

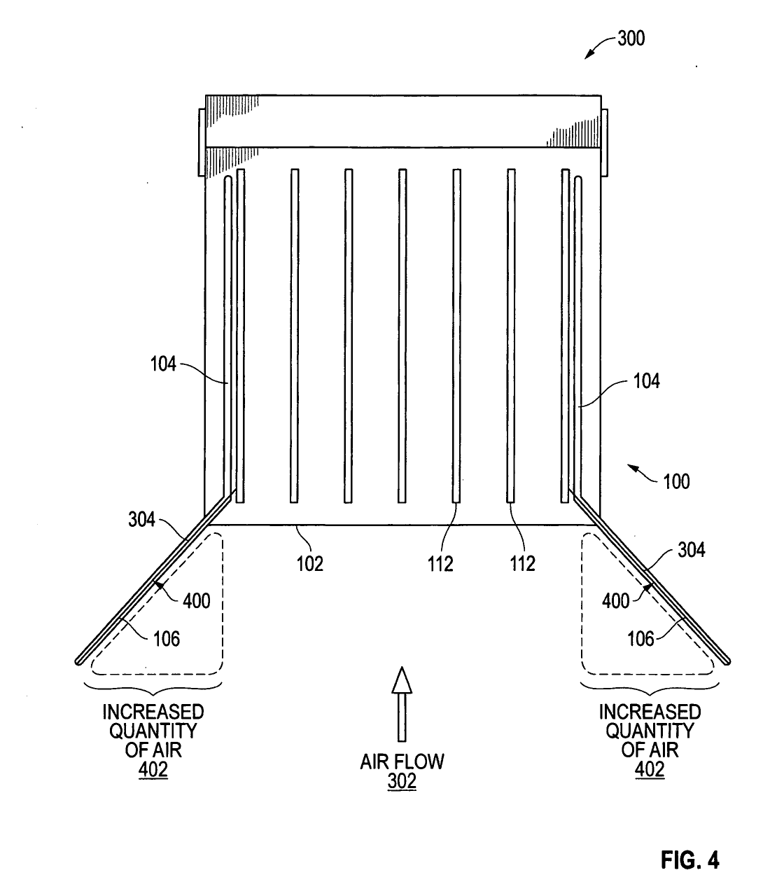

For further explanation of a baffle fin configured so as to control the air flow across the rigid heat-dissipating fins, FIG. 4 sets forth a top plan view of a further exemplary heat sink (100) for controlling dissipation of a thermal load according to embodiments of the present invention. The example heat sink (100) of FIG. 4 is similar to the example heat sink of FIG. 3. That is, similar to the example heat sink of FIG. 3 in that: The example heat sink (100) of FIG. 4 includes a heat sink base (102) receiving the thermal load. The heat sink base (102) receives the thermal load from an integrated circuit package (not shown). The example heat sink (100) of FIG. 4 includes rigid heat dissipating fins (112) connected to the heat sink base (102). The example heat sink (100) of FIG. 4 also includes a fan (300) oriented with respect to the rigid heat-dissipating fins (112) so as to induce air flow (302) across the rigid heat-dissipating fins (112). The example heat sink (100) of FIG. 4 also includes two actuators (104) connected to the heat sink base (102). Each actuator (104) has a temperature dependent upon the thermal load. Each actuator (104) is configured in dependence upon the temperature of the actuator (104). Each actuator (104) is implemented as a wire of a shape memory alloy. The example heat sink (100) of FIG. 4 also includes two adaptable fins (106). Each adaptable fin (106) is connected to one of the actuators (104).

In the example of FIG. 4, each adaptable fin (106) is shaped according to the configuration of the actuator (104) so as to control dissipation of the thermal load. That is, the geometry of the adaptable fin (106) changes as the position of the actuator (104) changes. To control dissipation of the thermal load, each adaptable fin (106) in the example of FIG. 4 is implemented as a baffle fin (304) configured so as to control the air flow (302) across the rigid heat-dissipating fins (112). Changes in the shape of the baffle fins (304) control the quantity of air flowing across the rigid heat-dissipating fins (112) with respect to time. When the actuators (104) expand the baffle fins (304), the actuators (304) insert the surfaces (400) of the baffle fins (304) into the path of the air flow (302) induced by fan (300). Inserting the surfaces (400) of the baffle fins (304) into the path of the air flow (302) funnels an increased quantity (402) of air across the rigid heat-dissipating fins (112), and air flow (302) therefore is increased. When the actuators (104) collapse the baffle fins (304), the actuators (304) remove the surfaces (400) of the baffle fins (304) from the path of the air flow (302) induced by fan (300). Removing the surfaces (400) of the baffle fins (304) from the path of the air flow (302) removes the increased quantity (402) of air from the air flow (302), and air flow (302) is decreased. As mentioned above, dissipation of the thermal load by the heat sink (100) occurs primarily by thermal convection through the surface of the heat sink (100) to the surrounding environment. The heat sink (100) dissipates the thermal load according to:
dQ/dt=−K*A*dT,
where Q is the instantaneous thermal energy in the heat sink, dQ/dt is the rate of dissipation of thermal energy by the heat sink expressed in Watts, K is thermal conductivity of the heat sink expressed in Watts/meters²/Kelvin, A is the surface area of the heat sink, and dT is the temperature gradient of the heat sink. Because increasing the air flow (302) across the rigid heat-dissipating fins (112) increases the thermal conductivity of the heat sink (100), increasing the air flow (302) allows the heat sink (100) to dissipate the thermal load at a lower temperature than dissipation of the thermal load without increasing the air flow (302). Similarly, decreasing the air flow (302) allows the heat sink (100) to dissipate the thermal load at a higher temperature than dissipation of the thermal load without decreasing the air flow (302). Therefore, as the actuators (104) expand and collapse the baffle fins (304), the heat sink (100) controls the dissipation of the thermal load.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A heat sink for controlling dissipation of a thermal load, the heat sink comprising:
a heat sink base receiving the thermal load;
an actuator connected to the heat sink base, the actuator having a temperature dependent upon the thermal load, the actuator configured in dependence upon the temperature of the actuator; and
an adaptable fin connected to the actuator and shaped according to the configuration of the actuator so as to control dissipation of the thermal load.

2. The heat sink of claim 1 wherein the actuator comprises a wire of a shape memory alloy.

3. The heat sink of claim 2 wherein the shape memory alloy is nitinol.

4. The heat sink of claim 1 wherein the adaptable fin comprises an adaptable heat-dissipating fin.

5. The heat sink of claim 4 wherein the adaptable heat-dissipating fin is copper foil.

6. The heat sink of claim 4 wherein the adaptable heat-dissipating fin is thermally conductive fabric.

7. The heat sink of claim 1 further comprising:
rigid heat-dissipating fins connected to the heat sink base; and
a fan oriented with respect to the rigid heat-dissipating fins so as to induce air flow across the rigid heat-dissipating fins,
wherein the adaptable fin comprises a baffle fin configured so as to control the air flow across the rigid heat-dissipating fins.

8. The heat sink of claim 7 wherein the baffle fin is plastic.

9. A method for controlling dissipation of a thermal load in a heat sink, the method comprising:
receiving the thermal load in a heat sink base of the heat sink;
connecting an actuator to the heat sink base, the actuator having a temperature dependent upon the thermal load, the actuator configured in dependence upon the temperature of the actuator; and
connecting an adaptable fin to the actuator, wherein the adaptable fin is shaped according to the configuration of the actuator.

10. The method of claim 9 wherein the actuator comprises a wire of a shape memory alloy.

11. The method of claim 10 wherein the shape memory alloy is nitinol.

12. The method of claim 9 wherein the adaptable fin comprises an adaptable heat-dissipating fin.

13. The method of claim 12 wherein the adaptable heat-dissipating fin is copper foil.

14. The method of claim 12 wherein the adaptable heat-dissipating fin is thermally conductive fabric.

15. The method of claim 9 further comprising:
connecting rigid heat-dissipating fins to the heat sink base; and
orienting a fan with respect to the rigid heat-dissipating fins so as to induce air flow across the rigid heat-dissipating fins,
wherein the adaptable fin comprises a baffle fin configured so as to control the air flow across the rigid heat-dissipating fins.

16. The method of claim 15 wherein the baffle fin is plastic.

17. A heat sink for controlling dissipation of a thermal load, the heat sink manufactured by the process of:
providing a heat sink base for receiving the thermal load;
connecting an actuator to the heat sink base, the actuator having a temperature dependent upon the thermal load, the actuator configured in dependence upon the temperature of the actuator; and
connecting an adaptable fin to the actuator, wherein the adaptable fin is shaped according to the configuration of the actuator.

18. The heat sink of claim 17 wherein the actuator comprises a wire of a shape memory alloy.

19. The heat sink of claim 18 wherein the shape memory alloy is nitinol.

20. The heat sink of claim 17 wherein the adaptable fin comprises an adaptable heat-dissipating fin.

21. The heat sink of claim 20 wherein the adaptable heat-dissipating fin is copper foil.

22. The heat sink of claim 20 wherein the adaptable heat-dissipating fin is thermally conductive fabric.

23. The heat sink of claim 17 further comprising:
connecting rigid heat-dissipating fins to the heat sink base; and
orienting a fan with respect to the rigid heat-dissipating fins so as to induce air flow across the rigid heat-dissipating fins,
wherein the adaptable fin comprises a baffle fin configured so as to control the air flow across the rigid heat-dissipating fins.

24. The heat sink of claim 23 wherein the baffle fin is plastic.
